(19) United States
(12) Patent Application Publication
(10) Pub. No.: US 2026/0176066 A1
(43) Pub. Date: Jun. 25, 2026

(54) AUTOMATED MATERIAL HANDLING SYSTEM

(71) Applicant: Taiwan Semiconductor Manufacturing Company Limited, Hsin-Chu (TW)

(72) Inventors: Guancyun LI, Hsinchu City (TW); Chen-Yang HSIEH, Hsin-Chu (TW); Ching-Jung CHANG, Taichung City (TW)

(21) Appl. No.: 18/991,823

(22) Filed: Dec. 23, 2024

(51) Int. Cl. B65G 1/04

(52) U.S. Cl. CPC B65G 1/0492

(57) ABSTRACT

An automated material handling system is provided. The automated material handling system includes a stocking apparatus including a plurality of shelving units. The automated material handling system includes an airflow rectification structure overlying one or more of the plurality of shelving units. The automated material handling system includes a vacuum unit under one or more of the plurality of shelving units, wherein the airflow rectification structure is configured to conduct air along one or more flow paths to the vacuum unit.

### BACKGROUND

Semiconductor devices are formed on, in, and/or from semiconductor wafers, and are used in a multitude of electronic devices, such as mobile phones, laptops, desktops, tablets, watches, gaming systems, and various other industrial, commercial, and consumer electronics. One or more semiconductor fabrication processes are performed to form semiconductor devices on, in, and/or from a semiconductor wafer. The semiconductor wafer is stored in a wafer storage device during a period between semiconductor fabrication processes.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1A illustrates a perspective view of an automated material handling system, in accordance with some embodiments.

FIG. 1B illustrates a perspective view of an airflow rectification structure comprising a honeycomb arrangement, in accordance with some embodiments.

FIG. 1C illustrates a section of an airflow rectification structure, in accordance with some embodiments.

FIG. 2A illustrates a front view of portion of a stocking apparatus, in accordance with some embodiments.

FIG. 2B illustrates a front view of portion of a stocking apparatus, in accordance with some embodiments.

FIG. 2C illustrates a perspective view of an automated material handling system, in accordance with some embodiments.

FIG. 2D illustrates a perspective view of an automated material handling system, in accordance with some embodiments.

FIG. 2E illustrates a perspective view of an automated material handling system, in accordance with some embodiments.

FIG. 2F illustrates a perspective view of an automated material handling system, in accordance with some embodiments.

FIG. 2G illustrates a perspective view of an automated material handling system, in accordance with some embodiments.

FIG. 2H illustrates a side view of a shelving unit, in accordance with some embodiments.

FIG. 3 illustrates a top view of a stocking vehicle, in accordance with some embodiments.

FIG. 4 is a flow diagram illustrating a method, in accordance with some embodiments.

FIG. 5 illustrates an example computer-readable medium wherein processor-executable instructions configured to embody one or more of the provisions set forth herein may be comprised, according to some embodiments.

### DETAILED DESCRIPTION

The following disclosure provides several different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact and may also include embodiments in which additional features may be formed between the first and second features, such that the first and second features may not be in direct contact. In addition, the present disclosure may repeat reference numerals or letters in the various examples. This repetition is for the purpose of simplicity and clarity and does not in itself dictate a relationship between the various embodiments or configurations discussed.

Further, spatially relative terms, such as “beneath,” “below,” “lower,” “above,” “upper” and the like, may be used herein for ease of description to describe one element or feature's relationship to other element(s) or feature(s) as illustrated in the figures. The spatially relative terms are intended to encompass different orientations of the device in use or operation in addition to the orientation illustrated in the figures. The apparatus may be otherwise oriented (rotated 90 degrees or at other orientations) and the spatially relative descriptors used herein may likewise be interpreted accordingly.

The term “overlying” and/or the like may be used to describe one element or feature being vertically coincident with and at a higher elevation than another element or feature. For example, a first element overlies a second element if the first element is at a higher elevation than the second element and at least a portion of the first element is vertically coincident with at least a portion of the second element.

The term “underlying” and/or the like may be used to describe one element or feature being vertically coincident with and at a lower elevation than another element or feature. For example, a first element underlies a second element if the first element is at a lower elevation than the second element and at least a portion of the first element is vertically coincident with at least a portion of the second element.

The term “over” may be used to describe one element or feature being at a higher elevation than another element or feature. For example, a first element is over a second element if the first element is at a higher elevation than the second element.

The term “under” may be used to describe one element or feature being at a lower elevation than another element or feature. For example, a first element is under a second element if the first element is at a lower elevation than the second element.

An automated material handling system has one or more mechanisms for controlling at least one of airflow or air quality of a stocking environment. The automated material handling system comprises a stocking apparatus including a plurality of shelving units. Product units, such as wafer storage devices carrying semiconductor wafers, are stored in storage locations of shelving units of the stocking apparatus. In accordance with some embodiments, the automated material handling system comprises an airflow rectification structure overlying one or more of the plurality of shelving units. The automated material handling system includes a vacuum unit under one or more of the plurality of shelving units, wherein the airflow rectification structure is configured to conduct air along one or more flow paths to at least one of (i) a space under one or more of the plurality of shelving units or (ii) a vacuum unit under one or more of the plurality of shelving units. The vacuum unit is controlled based upon an air particulate metric associated with a stocking environment of the automated material handling system. The vacuum unit is activated to intake air, such as particle-laden air, in response to the air particulate metric meeting a threshold, thereby providing improved air quality of the stocking environment. In some embodiments, one or more fan units, such as filter fan units, are arranged over the airflow rectification structure, and are configured to emit one or more air streams to the airflow rectification structure. In some embodiments, the one or more fan units have a ceiling coverage rate that exceeds a threshold ceiling coverage rate. The automated material handling system having at least one of (i) the one or more fan units that meet the threshold ceiling coverage rate, (ii) the airflow rectification structure under the one or more fan units, or (iii) the vacuum unit under one or more of the plurality of shelving units provides for benefits including at least one of (A) increased directional uniformity of airflow (e.g., downwards airflow) flowing through and/or around the stocking apparatus (e.g., straightened airflow flowing in vertical downwards direction), (B) reduced turbulence (e.g., longitudinal and/or lateral turbulence) in and around the stocking apparatus, (C) improved stability of airflow (e.g., achievement of a down flow steady state in and/or around the stocking apparatus), etc. Turbulence introduces irregular (e.g., upwards and/or lateral) forces that cause particles to become airborne or keep the particles suspended in the air for longer. At least one of the increased directional uniformity of airflow or the reduced turbulence provides for reduced air-laden particles (e.g., contaminants, dust, processing chemicals, etc.) in the stocking environment, thereby providing for improved quality and/or cleanliness of wafers stored in wafer storage devices that are stored in the stocking apparatus. Wafers with improved quality, cleanliness, etc. generally yield higher quality semiconductor devices (e.g., that operate more reliably, consistently, predictably, longer, etc.).

In some embodiments, a shelving unit of the stocking apparatus comprises at least one of a first stopper, a second stopper, or a gate assembly between the first stopper and the second stopper. In some embodiments, the gate assembly is configured to control a state of a stocking path between the first stopper and the second stopper. The gate assembly is configured to open the stocking path in response to receiving a stocking operation message indicative of a stocking operation. The gate assembly is configured to close the stocking path in response to completion of the stocking operation. In some embodiments, the gate assembly keeps the stocking path closed during a period of time during which no stocking operation associated with the shelving unit is scheduled and/or performed. The gate assembly being closed mitigates flow of air (e.g., particle-laden air) and/or particles into the shelving unit, thereby providing for reduced air-laden particles (e.g., contaminants, dust, processing chemicals, etc.) in the shelving unit and/or improved quality and/or cleanliness of wafers stored in wafer storage devices that are stored in the stocking apparatus. In some embodiments, at least one of the first stopper or the second stopper is curved to at least one of (i) promote laminar airflow, (ii) mitigate flow of air and/or particles into the shelving unit, or (iii) mitigate turbulence.

In some embodiments, the automated material handling system comprises one or more windshields coupled to the stocking vehicle. In some embodiments, one or more corners of the stocking vehicle are rounded. The one or more windshields and/or the one or more corners of the stocking vehicle being rounded at least one of (i) promote laminar airflow relative to the stocking vehicle during movement of the stocking vehicle, (ii) mitigate turbulence, (iii) improve aerodynamics of the stocking vehicle, or (iv) reduce drag of the stocking vehicle during movement of the stocking vehicle.

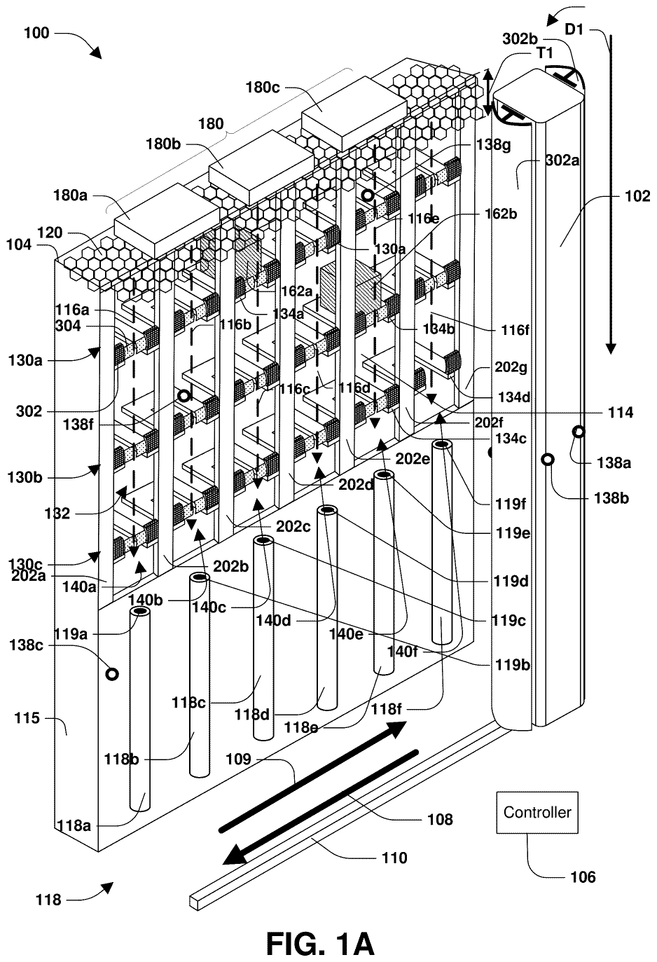

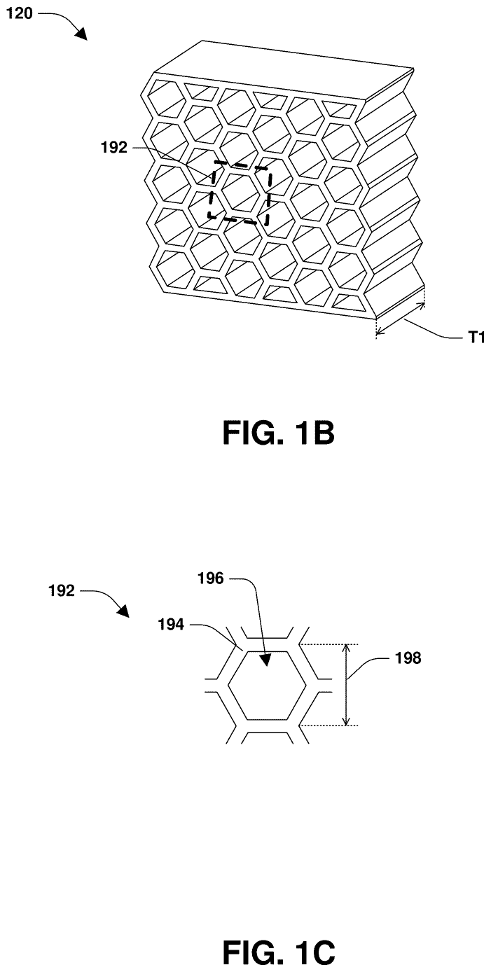

FIG. 1A illustrates an automated material handling system 100 for transporting and/or storing product units according to some embodiments. In some embodiments, the automated material handling system 100 comprises a stocking apparatus 104 comprising a plurality of shelving units. In some embodiments, each shelving unit of one, some, or all of the plurality of shelving units is configured to store a product unit, such as a wafer storage device. The plurality of shelving units are arranged across rows 130a, 130b and 130c. Although FIG. 1A shows three rows, other numbers of rows of shelving units of the stocking apparatus 104 other than three rows are within the scope of the present disclosure. The plurality of shelving units are arranged across columns 140a, 140b, 140c, 140d, 140e, and 140f. Although FIG. 1A shows six columns, other numbers of columns of shelving units of the stocking apparatus 104 other than six columns are within the scope of the present disclosure. In some embodiments, a product unit 162a (e.g., a wafer storage device) is stored in a storage location over a shelving unit 134a of the plurality of shelving units. In some embodiments, a product unit 162b (e.g., a wafer storage device) is stored in a storage location over a shelving unit 134b of the plurality of shelving units. In some embodiments, each shelving unit of one, some, or all of the plurality of shelving units is affixed to a wall 114, such as a storage partition wall of the automated material handling system 100.

In some embodiments, the automated material handling system 100 comprises a stocking vehicle 102. In some embodiments, the stocking vehicle 102 comprises at least one of a transport vehicle, an overhead transport vehicle, a guided transport vehicle that travels on predetermined routes or tracks, a crane, a forklift, an arm, or other suitable vehicle. In some embodiments, the automated material handling system 100 comprises one or more tracks, such as track 110, to guide movement of the stocking vehicle 102. In some embodiments, the stocking vehicle 102 moves in directions 108 and 109 along the track 110 while the stocking vehicle 102 is engaged with the track 110. In some embodiments, the stocking vehicle 102 performs a stocking operation of a product unit. In some embodiments, the stocking operation comprises transferring the product unit to or from a storage location over a shelving unit of the plurality of shelving units.

In some embodiments, the automated material handling system 100 comprises an airflow rectification structure 120 (e.g., an airflow rectifier and/or straightener) overlying one or more of the plurality of shelving units. In some embodiments, the airflow rectification structure 120 is configured to conduct air along a set of flow paths (e.g., a set of one or more flow paths). In some embodiments, the airflow rectification structure 120 is configured to at least one of (i) promote (e.g., increase) airflow (e.g., straightened airflow) in a first direction D1 (e.g., vertical downwards direction or other suitable direction), or (ii) mitigate (e.g., reduce, inhibit and/or block) airflow (e.g., longitudinal and/or lateral turbulence) in one or more directions away from the first direction D1. In some embodiments, the set of flow paths comprises at least one of a first flow path 116a, a second flow path 116b, a third flow path 116c, a fourth flow path 116d, a fifth flow path 116e, a sixth flow path 116f, or one or more other flow paths. Although FIG. 1A shows six flow paths, other numbers of flow paths of flow paths of the set of flow paths other than six flow paths are within the scope of the present disclosure. In some embodiments, each flow path of one, some, or all of the set of flow paths is about parallel to the first direction D1. In some embodiments, one or more of the set of flow paths (e.g., at least one of the first flow path 116a, the second flow path 116b, the third flow path 116c, the fourth flow path 116d, the fifth flow path 116e, the sixth flow path 116f, etc.) extend through a chamber 132 defined by the one or more walls (e.g., at least one of the wall 114, a wall 115, etc.) of the stocking apparatus 104. In some embodiments, one or more of the set of flow paths (e.g., at least one of the first flow path 116a, the second flow path 116b, the third flow path 116c, the fourth flow path 116d, the fifth flow path 116e, the sixth flow path 116f, etc.) are outside the chamber 132. In some embodiments, air is conducted (by the airflow rectification structure 120, for example) along one or more flow paths of the set of flow paths to a space under one, some or all of the plurality of shelving units of the stocking apparatus 104.

In some embodiments, the airflow rectification structure 120 comprises a honeycomb arrangement (e.g., a honeycomb grid, one or more features having trapezoidal cross-sections, etc.). In some embodiments, the honeycomb arrangement at least one of (i) breaks up turbulence (e.g., honeycomb cells of the honeycomb arrangement disrupt and/or dissipate turbulent airflow to create a more uniform and/or stable flow), (ii) mitigates creation of at least one of swirls, eddies, etc., (iii) improves flow stability, or (iv) mitigates lateral turbulence. In some embodiments, the airflow rectification structure 120 (e.g., the honeycomb arrangement) comprises at least one of plastic or other suitable material. A thickness T1 (shown in FIG. 1A and FIG. 1B) of the airflow rectification structure 120 is at least one of (i) between about 1 centimeter to about 10 centimeters, (ii) between about 1 centimeter to about 24 centimeters, or (iii) about 5 centimeters. Other values of the thickness T1 are within the scope of the present disclosure.

FIG. 1B illustrates a perspective view of the airflow rectification structure 120 comprising the honeycomb arrangement, in accordance with some embodiments. FIG. 1C illustrates a section 192 of the airflow rectification structure 120 depicted in FIG. 1B, in accordance with some embodiments. In some embodiments, the section 192 of the airflow rectification structure 120 comprises a honeycomb cell 194 defining an opening 196 through which air is conducted. In some embodiments, a honeycomb cell size 198 of the honeycomb cell 194 is based upon a flow speed with which air flows through the stocking apparatus 104. In some embodiments, the honeycomb cell size 198 of the honeycomb cell 194 is at most about the thickness T1 divided by six. In some embodiments, setting the honeycomb cell size 198 associated with the honeycomb cell 194 to be at most about the thickness T1 divided by six provides for reduced axial turbulence in the stocking apparatus 104. The honeycomb cell size 198 is between about 2 centimeters to about 4 centimeters. Other values of the honeycomb cell size 198 are within the scope of the present disclosure.

In some embodiments, the automated material handling system 100 comprises a set of vacuum units 118 (e.g., a set of one or more vacuum units). In some embodiments, the set of vacuum units 118 comprises at least one of a first vacuum unit 118a, a second vacuum unit 118b, a third vacuum unit 118c, a fourth vacuum unit 118d, a fifth vacuum unit 118e, a sixth vacuum unit 118f, or one or more other vacuum units. Although FIG. 1A shows six vacuum units, other numbers of vacuum units of vacuum units of the set of vacuum units 118 other than six vacuum units are within the scope of the present disclosure.

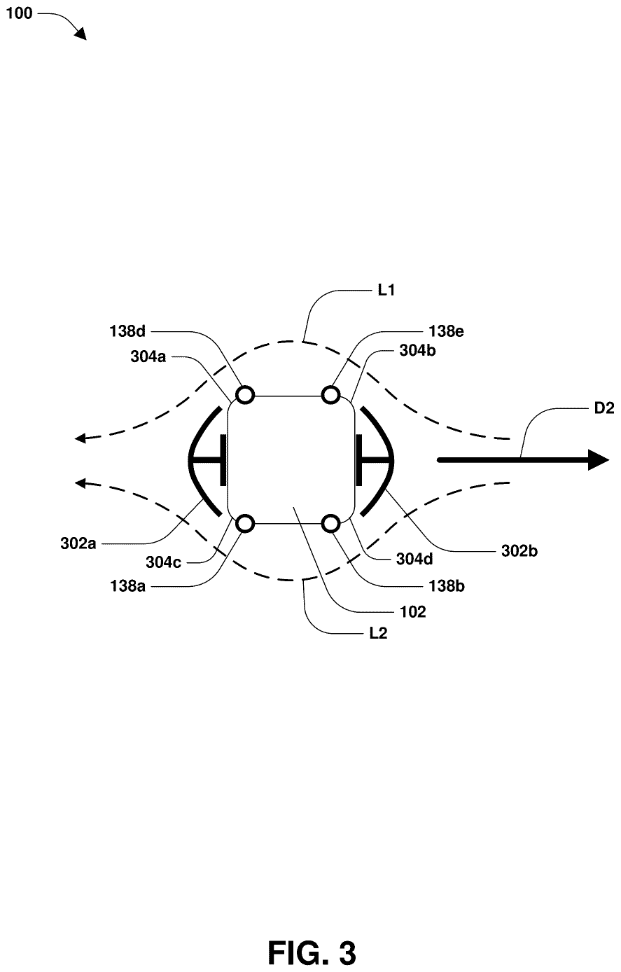

In some embodiments, the automated material handling system 100 comprises a set of air particulate sensors (e.g., a set of one or more air particulate sensors). In some embodiments, each air particulate sensor (e.g., particle counter) of one, some or all of the set of air particulate sensors is configured to measure an air particulate metric (e.g., particle count) associated with a stocking environment 150 associated with the automated material handling system 100. In some embodiments, the set of air particulate sensors comprises at least one of a first air particulate sensor 138a (coupled to the stocking vehicle 102, for example), a second air particulate sensor 138b (coupled to the stocking vehicle 102, for example), a third air particulate sensor 138c (positioned proximal to a vacuum unit of the set of vacuum units 118, for example), a fourth air particulate sensor 138d (shown in FIG. 3), a fifth air particulate sensor 138e (e.g., at least one of the fourth air particulate sensor 138d or the fifth air particulate sensor 138e is coupled to the stocking vehicle 102, for example), a set of shelving area air particulate sensors (e.g., a set of one or more air particulate sensors), or one or more other air particulate sensors.

In some embodiments, the set of shelving area air particulate sensors comprises sensors at different elevations. In some embodiments, the set of shelving area air particulate sensors comprises at least one of (i) one or more first air particulate sensors at a first elevation or (ii) one or more second air particulate sensors at a second elevation different than the first elevation. In some embodiments, the one or more first air particulate sensors comprise at least one of a sixth air particulate sensor 138f or one or more other air particulate sensors. In some embodiments, the one or more second air particulate sensors comprise at least one of a seventh air particulate sensor 138g or one or more other air particulate sensors. Although the drawings of the present disclosure show seven air particulate sensors, other numbers of air particulate sensors of air particulate sensors of the set of air particulate sensors other than seven air particulate sensors are within the scope of the present disclosure. In some embodiments, an elevation of a sensor of the set of shelving area air particulate sensors impacts an air particulate metric measured by the sensor, such as due, at least in part, to levels of air particles changing (e.g., increasing) along the first direction D1.

In some embodiments, the set of air particulate sensors produce a set of air particulate metrics (e.g., a set of one or more air particulate metrics) comprising at least one of a first air particulate metric measured by the first air particulate sensor 138a, a second air particulate metric measured by the second air particulate sensor 138b, a third air particulate metric measured by the third air particulate sensor 138c, an air particulate metric measured by the fourth air particulate sensor 138d, an air particulate metric measured by the fifth air particulate sensor 138e, one or more air particulate metrics measured by the set of shelving area air particulate sensors, or one or more other air particulate metrics. In some embodiments, operation of one or more vacuum units of the set of vacuum units 118 is controlled based upon the set of air particulate metrics. In some embodiments, the set of air particulate metrics are combined (e.g., averaged) to determine an aggregate air particulate metric (e.g., an average of the set of air particulate metrics). In some embodiments, operation of one or more vacuum units of the set of vacuum units 118 is controlled based upon the aggregate air particulate metric.

In some embodiments, the automated material handling system 100 comprises a controller 106 configured to control operation of the set of vacuum units 118. In some embodiments, the controller 106 communicates with the set of vacuum units 118 over at least one of a wired connection, a wireless connection, etc. to control operation of (e.g., activate and/or deactivate) the set of vacuum units 118. In some embodiments, the controller 106 controls operation of the set of vacuum units 118 based upon a fourth air particulate metric (e.g., the aggregate air particulate metric or an air particulate metric of the set of air particulate metrics). In some embodiments, the controller 106 determines the fourth air particulate metric based upon one or more signals received by the controller 106 from the set of air particulate sensors. In some embodiments, the one or more signals are received by the controller 106 from the set of air particulate sensors over at least one of a wired connection, a wireless connection, etc. In some embodiments, the controller 106 controls operation of the set of vacuum units 118 based upon a comparison of the fourth air particulate metric with a first air particulate threshold and/or a second air particulate threshold.

In some embodiments, a vacuum unit of the set of vacuum units 118 is activated to intake air (e.g., particle-laden air) from the stocking environment 150. In some embodiments, the vacuum unit (e.g., at least one of the first vacuum unit 118a, the second vacuum unit 118b, the third vacuum unit 118c, the fourth vacuum unit 118d, the fifth vacuum unit 118e, the sixth vacuum unit 118f, etc.) intakes air (e.g., particle-laden air) from the stocking environment 150 through an inlet (e.g., at least one of an inlet 119a of the first vacuum unit 118a, an inlet 119b of the second vacuum unit 118b, an inlet 119c of the third vacuum unit 118c, an inlet 119d of the fourth vacuum unit 118d, an inlet 119e of the fifth vacuum unit 118e, an inlet 119f of the sixth vacuum unit 118f, etc.). In some embodiments, the vacuum unit conducts the air to a filter that traps particles from the air (to produced filtered air, for example). In some embodiments, the controller 106 activates the vacuum unit (to intake air through the inlet and/or filter the air, for example) by transmitting an activation signal to the vacuum unit. In some embodiments, the controller 106 compares the fourth air particulate metric with the first air particulate threshold. In some embodiments, the controller 106 activates the vacuum unit (to intake air through the inlet and/or filter the air, for example) in response to a determination that the fourth air particulate metric meets (e.g., exceeds) the first air particulate threshold. The first air particulate threshold is at least one of (i) between about 10,000 first-sized particles per cubic meter of air to about 200,000 first-sized particles per cubic meter of air, (ii) about 100,000 first-sized particles per cubic meter of air, (iii) between about 1,000 second-sized particles per cubic meter of air to about 40,000 second-sized particles per cubic meter of air, (iv) about 23,700 second-sized particles per cubic meter of air, (v) between about 500 third-sized particles per cubic meter of air to about 20,000 third-sized particles per cubic meter of air, (vi) about 10,200 third-sized particles per cubic meter of air, (vii) between about 300 fourth-sized particles per cubic meter of air to about 15,000 fourth-sized particles per cubic meter of air, (viii) about 3,520 fourth-sized particles per cubic meter of air, (ix) between about 100 fifth-sized particles per cubic meter of air to about 5,000 fifth-sized particles per cubic meter of air, (x) about 832 fifth-sized particles per cubic meter of air, (xi) between about 10 sixth-sized particles per cubic meter of air to about 100 sixth-sized particles per cubic meter of air, or (xii) about 29 sixth-sized particles per cubic meter of air. Other values of the first air particulate threshold are within the scope of the present disclosure. In some embodiments, first-sized particles correspond to particles having particle sizes that are at least about a first threshold particle size, such as 0.1 micrometers (e.g., in diameter, cross-section, etc.). In some embodiments, second-sized particles correspond to particles having particle sizes that are at least about a second threshold particle size, such as 0.2 micrometers (e.g., in diameter, cross-section, etc.). In some embodiments, third-sized particles correspond to particles having particle sizes that are at least about a third threshold particle size, such as 0.3 micrometers (e.g., in diameter, cross-section, etc.). In some embodiments, fourth-sized particles correspond to particles having particle sizes that are at least about a fourth threshold particle size, such as 0.5 micrometers (e.g., in diameter, cross-section, etc.). In some embodiments, fifth-sized particles correspond to particles having particle sizes that are at least about a fifth threshold particle size, such as 1 micrometer (e.g., in diameter, cross-section, etc.). In some embodiments, sixth-sized particles correspond to particles having particle sizes that are at least about a sixth threshold particle size, such as 5 micrometers (e.g., in diameter, cross-section, etc.).

In some embodiments, after (and/or while) the vacuum unit is activated (e.g., while the vacuum unit intakes and/or filters air from the stocking environment 150), the controller 106 monitors the one or more signals from the set of air particulate sensors to detect an update to an air particulate metric of the set of air particulate metrics (e.g., a change to at least one of the first air particulate metric measured by the first air particulate sensor 138a, the second air particulate metric measured by the second air particulate sensor 138b, the third air particulate metric measured by the third air particulate sensor 138c, the air particulate metric measured by the fourth air particulate sensor 138d, the air particulate metric measured by the fifth air particulate sensor 138e, an air particulate metric of the one or more air particulate metrics measured by the set of shelving area air particulate sensors, etc.). In some embodiments, in response to detecting the update to the air particulate metric of the set of air particulate metrics, the controller 106 determines an updated value of the fourth air particulate metric (based upon updated values of the set of air particulate metrics, for example). In some embodiments, the controller 106 compares the updated value of the fourth air particulate metric with the second air particulate threshold. In some embodiments, the controller 106 monitors the fourth air particulate metric by (i) determining one or more updated values of the fourth air particulate metric over time, and (ii) comparing the one or more updated values of the fourth air particulate metric with the first air particulate threshold and/or the second air particulate threshold.

In some embodiments, the vacuum unit is deactivated to cease intake of air in response to the updated value of the air particulate metric not meeting the second air particulate threshold. In some embodiments, the controller 106 deactivates the vacuum unit by transmitting a deactivation signal to the vacuum unit. In some embodiments, the controller 106 deactivates the vacuum unit (to cease intake of air through the inlet and/or cease filtering the air, for example) in response to a determination that the updated value of the fourth air particulate metric does not meet (e.g., does not exceed) the second air particulate threshold. In some embodiments, the second air particulate threshold is the same as the first air particulate threshold. In some embodiments, the second air particulate threshold is different than the first air particulate threshold. The second air particulate threshold is at least one of (i) between about 10,000 first-sized particles per cubic meter of air to about 200,000 first-sized particles per cubic meter of air, (ii) about 100,000 first-sized particles per cubic meter of air, (iii) between about 1,000 second-sized particles per cubic meter of air to about 40,000 second-sized particles per cubic meter of air, (iv) about 23,700 second-sized particles per cubic meter of air, (v) between about 500 third-sized particles per cubic meter of air to about 20,000 third-sized particles per cubic meter of air, (vi) about 10,200 third-sized particles per cubic meter of air, (vii) between about 300 fourth-sized particles per cubic meter of air to about 15,000 fourth-sized particles per cubic meter of air, (viii) about 3,520 fourth-sized particles per cubic meter of air, (ix) between about 100 fifth-sized particles per cubic meter of air to about 5,000 fifth-sized particles per cubic meter of air, (x) about 832 fifth-sized particles per cubic meter of air, (xi) between about 10 sixth-sized particles per cubic meter of air to about 100 sixth-sized particles per cubic meter of air, or (xii) about 29 sixth-sized particles per cubic meter of air. Other values of the second air particulate threshold are within the scope of the present disclosure.

In some embodiments, the controller 106 determines a plurality of zone-based air particulate metrics associated with a plurality of shelving zones of the stocking apparatus 104 and selectively controls the set of vacuum units 118 based upon the plurality of zone-based air particulate metrics. In some embodiments, the plurality of zone-based air particulate metrics comprises at least one of a first zone air particulate metric associated with a first shelving zone of the stocking apparatus 104, a second zone air particulate metric associated with a second shelving zone of the stocking apparatus 104, etc. In some embodiments, the first shelving zone encompasses an area in which one or more first shelving units (e.g., some or all shelving units of columns 140a, 140b, and 140c) are disposed. In some embodiments, at least one of the sixth air particulate sensor 138f or one or more other air particulate sensors is in the first shelving zone. In some embodiments, the controller 106 determines the first zone air particulate metric based upon at least one of an air particulate metric measured by the sixth air particulate sensor 138f or one or more air particulate metrics measured by the one or more other air particulate sensors in the first shelving zone. In some embodiments, the controller 106 controls operation of one or more first vacuum units of the set of vacuum units 118 based upon the first zone air particulate metric, such as based upon a comparison of the first zone air particulate metric with a threshold (e.g., at least one of the first air particulate threshold or the second air particulate threshold). In some embodiments, the one or more first vacuum units comprise at least one of the first vacuum unit 118a, the second vacuum unit 118b, or the third vacuum unit 118c.

In some embodiments, the second shelving zone encompasses an area in which one or more second shelving units (e.g., some or all shelving units of columns 140d, 140e, and 140f) are disposed. In some embodiments, at least one of the seventh air particulate sensor 138g or one or more other air particulate sensors is in the second shelving zone. In some embodiments, the controller 106 determines the second zone air particulate metric based upon at least one of an air particulate metric measured by the seventh air particulate sensor 138g or one or more air particulate metrics measured by the one or more other air particulate sensors in the second shelving zone. In some embodiments, the controller 106 controls operation of one or more second vacuum units of the set of vacuum units 118 based upon the second zone air particulate metric, such as based upon a comparison of the second zone air particulate metric with a threshold (e.g., at least one of the first air particulate threshold or the second air particulate threshold). In some embodiments, the one or more second vacuum units comprise at least one of the fourth vacuum unit 118d, the fifth vacuum unit 118e, or the sixth vacuum unit 118f.

In some embodiments, at a first time, the one or more first vacuum units are activated (e.g., based upon a determination that the first zone air particulate metric meets the first air particulate threshold) and the one or more second vacuum units are deactivated (e.g., based upon a determination that the that the second zone air particulate metric does not meet the first air particulate threshold). In some embodiments, at a second time, the one or more first vacuum units are deactivated (e.g., based upon a determination that the first zone air particulate metric does not meet the first air particulate threshold) and the one or more second vacuum units are activated (e.g., based upon a determination that the that the second zone air particulate metric meets the first air particulate threshold).

In some embodiments, the automated material handling system 100 comprises a set of fan units 180 (e.g., a set of one or more fan filter units (FFUs)). In some embodiments, one, some, or all of the set of fan units 180 overlie the airflow rectification structure 120. In some embodiments, one, some or all of the set of fan units 180 are in contact with the airflow rectification structure 120 (e.g., in contact with a top surface of the airflow rectification structure 120). In some embodiments, a space is defined between the set of fan units 180 and the airflow rectification structure 120, wherein an air stream emitted by the set of fan units 180 travels through the space into the airflow rectification structure 120. In some embodiments, the set of fan units 180 comprises at least one of a first fan unit 180a, a second fan unit 180b, a third fan unit 180c, or one or more other fan units. Although FIG. 1A shows three fan units, other numbers of fan units of fan units of the set of fan units 180 other than three fan units are within the scope of the present disclosure. In some embodiments, each fan unit of one, some or all of the set of fan units 180 is configured to emit an air stream (e.g., a filtered air stream) to the airflow rectification structure 120, wherein the airflow rectification structure 120 at least one of (i) rectifies the air stream and/or mitigates turbulence of the air stream to produce air flow predominantly traveling in one or more directions comprising the first direction D1, or (iii) conducts the air flow along one or more flow paths (of the set of flow paths, for example) to at least one of the set of vacuum units 118 or a space under one, some or all of the plurality of shelving units of the stocking apparatus 104. In some embodiments, each fan unit of one, some, or all of the set of fan units 180 comprises a filter to filter air particles from air to produce filtered air, wherein an air stream emitted by the fan unit comprises the filtered air.

In some embodiments, one, some, or all of the set of fan units 180 are arranged across and/or within a ceiling of the stocking apparatus 104. In some embodiments, the set of fan units 180 have a ceiling coverage rate that exceeds a threshold ceiling coverage rate. In some embodiments, the ceiling coverage rate corresponds to a percentage of the ceiling of the stocking apparatus 104 that is covered by (and/or proximal to) fan units of the set of fan units 180. The threshold ceiling coverage rate is at least one of (i) between about 60% to about 95%, (ii) between about 80% to about 90%, or (iii) about 85%. Other values of the threshold ceiling coverage rate are within the scope of the present disclosure. In some embodiments, configuring the set of fan units 180 such that the ceiling coverage rate exceeds the threshold ceiling coverage rate at least one of (i) provides more uniform airflow throughout the stocking apparatus 104, promotes (e.g., increases) airflow (e.g., straightened airflow) in the first direction D1 (e.g., vertical downwards direction), or (iii) mitigates (e.g., reduces, inhibits and/or blocks) airflow (e.g., longitudinal and/or lateral turbulence) in one or more directions away from the first direction D1. In some embodiments, the ceiling coverage rate is a function of at least one of a fan size associated with one, some, or all of the set of fan units 180 or a number of fan units of the set of fan units 180. In some embodiments, an increase of the fan size corresponds to an increase of the ceiling coverage rate. In some embodiments, the fan size corresponds to an outlet size associated with a fan unit of the set of fan units 180. In some embodiments, an increase of the number of fan units corresponds to an increase of the ceiling coverage rate. In some embodiments, at least one of the fan size or the number of fan units is configured such that the ceiling coverage rate exceeds the threshold ceiling coverage rate.

In some embodiments, the controller 106 communicates with a fan unit (e.g., at least one of the first fan unit 180a, the second fan unit 180b, the third fan unit 180c, etc.) of the set of fan units 180 over at least one of a wired connection, a wireless connection, etc. to control a flow rate of an air stream emitted by the fan unit. In some embodiments, in response to determining that the fourth air particulate metric meets (e.g., exceeds) a third air particulate threshold, the controller 106 at least one of (i) increases the flow rate of the air stream emitted by the fan unit, or (ii) activates the fan unit to trigger the fan unit to emit the air stream. In some embodiments, the third air particulate threshold is the same as the first air particulate threshold. In some embodiments, the third air particulate threshold is different than the first air particulate threshold. The third air particulate threshold is at least one of (i) between about 10,000 first-sized particles per cubic meter of air to about 200,000 first-sized particles per cubic meter of air, (ii) about 100,000 first-sized particles per cubic meter of air, (iii) between about 1,000 second-sized particles per cubic meter of air to about 40,000 second-sized particles per cubic meter of air, (iv) about 23,700 second-sized particles per cubic meter of air, (v) between about 500 third-sized particles per cubic meter of air to about 20,000 third-sized particles per cubic meter of air, (vi) about 10,200 third-sized particles per cubic meter of air, (vii) between about 300 fourth-sized particles per cubic meter of air to about 15,000 fourth-sized particles per cubic meter of air, (viii) about 3,520 fourth-sized particles per cubic meter of air, (ix) between about 100 fifth-sized particles per cubic meter of air to about 5,000 fifth-sized particles per cubic meter of air, (x) about 832 fifth-sized particles per cubic meter of air, (xi) between about 10 sixth-sized particles per cubic meter of air to about 100 sixth-sized particles per cubic meter of air, or (xii) about 29 sixth-sized particles per cubic meter of air. Other values of the third air particulate threshold are within the scope of the present disclosure. In some embodiments, the controller 106 increases the flow rate by transmitting a signal, indicative of increasing the flow rate to an increased flow rate, to the fan unit. In some embodiments, the controller 106 activates the fan unit by transmitting a signal, indicative of activation of the fan unit, to the fan unit.

In some embodiments, in response to determining that the fourth air particulate metric does not meet (e.g., does not exceed) a fourth air particulate threshold, the controller 106 at least one of (i) decreases the flow rate of the air stream emitted by the fan unit, or (ii) deactivates the fan unit to trigger the fan unit to cease emitting the air stream. In some embodiments, the controller 106 decreases the flow rate by transmitting a signal, indicative of decreasing the flow rate to a decreased flow rate, to the fan unit. In some embodiments, the controller 106 deactivates the fan unit by transmitting a signal, indicative of activation of the fan unit, to the fan unit. In some embodiments, the fourth air particulate threshold is the same as the second air particulate threshold. In some embodiments, the fourth air particulate threshold is different than the second air particulate threshold. The fourth air particulate threshold is at least one of (i) between about 10,000 first-sized particles per cubic meter of air to about 200,000 first-sized particles per cubic meter of air, (ii) about 100,000 first-sized particles per cubic meter of air, (iii) between about 1,000 second-sized particles per cubic meter of air to about 40,000 second-sized particles per cubic meter of air, (iv) about 23,700 second-sized particles per cubic meter of air, (v) between about 500 third-sized particles per cubic meter of air to about 20,000 third-sized particles per cubic meter of air, (vi) about 10,200 third-sized particles per cubic meter of air, (vii) between about 300 fourth-sized particles per cubic meter of air to about 15,000 fourth-sized particles per cubic meter of air, (viii) about 3,520 fourth-sized particles per cubic meter of air, (ix) between about 100 fifth-sized particles per cubic meter of air to about 5,000 fifth-sized particles per cubic meter of air, (x) about 832 fifth-sized particles per cubic meter of air, (xi) between about 10 sixth-sized particles per cubic meter of air to about 100 sixth-sized particles per cubic meter of air, or (xii) about 29 sixth-sized particles per cubic meter of air. Other values of the third air particulate threshold are within the scope of the present disclosure.

In some embodiments, the stocking apparatus 104 comprises a set of air conduction panes (e.g., a set of one or more air conduction panes). In some embodiments, each pane of one, some or all of the set of air conduction panes comprises a board (e.g., a seal board) comprising at least one of metal or other suitable material. In some embodiments, the set of air conduction panes comprises air conduction panes arranged adjacent to (and/or between pairs of) columns 140a, 140b, 140c, 140d, 140e, and/or 140f. In some embodiments, the set of air conduction panes comprises at least one of (i) a first air conduction pane 202a adjacent to the column 140a of shelving units, (ii) a second air conduction pane 202b adjacent to (and/or between) columns 140a and 140b, (iii) a third air conduction pane 202c adjacent to (and/or between) columns 140b and 140c, (iv) a fourth air conduction pane 202d adjacent to (and/or between) columns 140c and 140d, (v) a fifth air conduction pane 202e adjacent to (and/or between) columns 140d and 140e, (vi) a sixth air conduction pane 202f adjacent to (and/or between) columns 140e and 140f, (vii) a seventh air conduction pane 202g adjacent to column 140f, or (viii) one or more other suitable air conduction panes. In some embodiments, each air conduction pane of one, some or all of the set of air conduction panes is configured to (i) mitigate airflow (e.g., turbulent airflow of particle-laden air) from outside the chamber 132 to inside the chamber 132, (ii) mitigate airflow (e.g., turbulent airflow) from inside the chamber 132 to outside the chamber 132, (ii) promote (e.g., increase) airflow (e.g., straightened airflow) in the first direction D1 (e.g., vertical downwards direction), or (iii) mitigate (e.g., reduce, inhibit and/or block) airflow (e.g., longitudinal and/or lateral turbulence) in one or more directions away from the first direction D1.

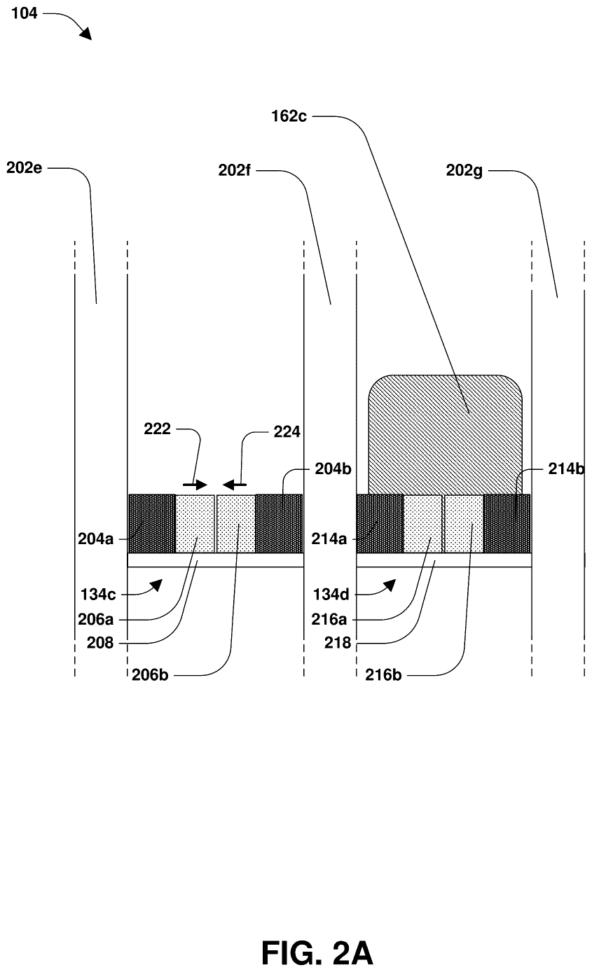

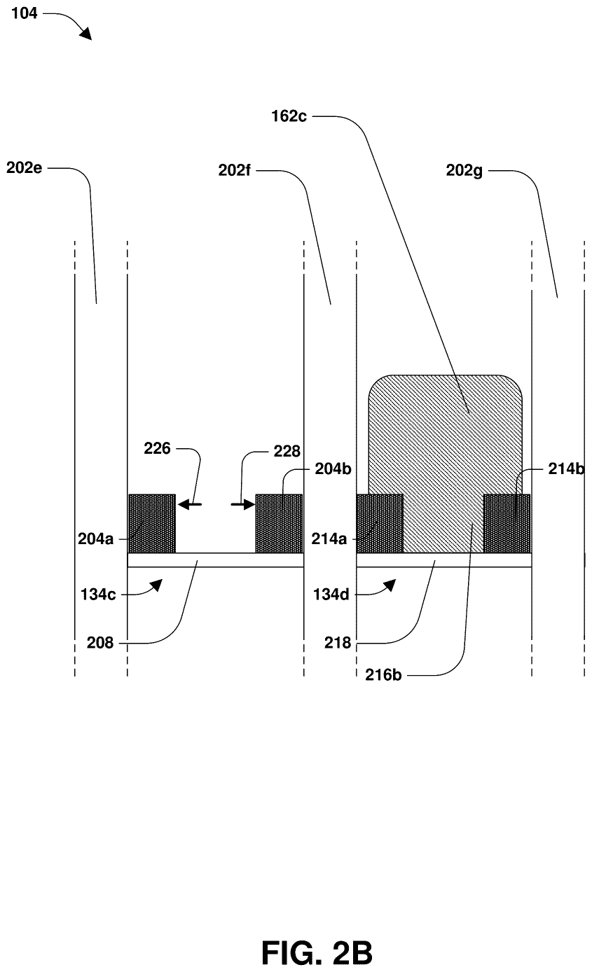

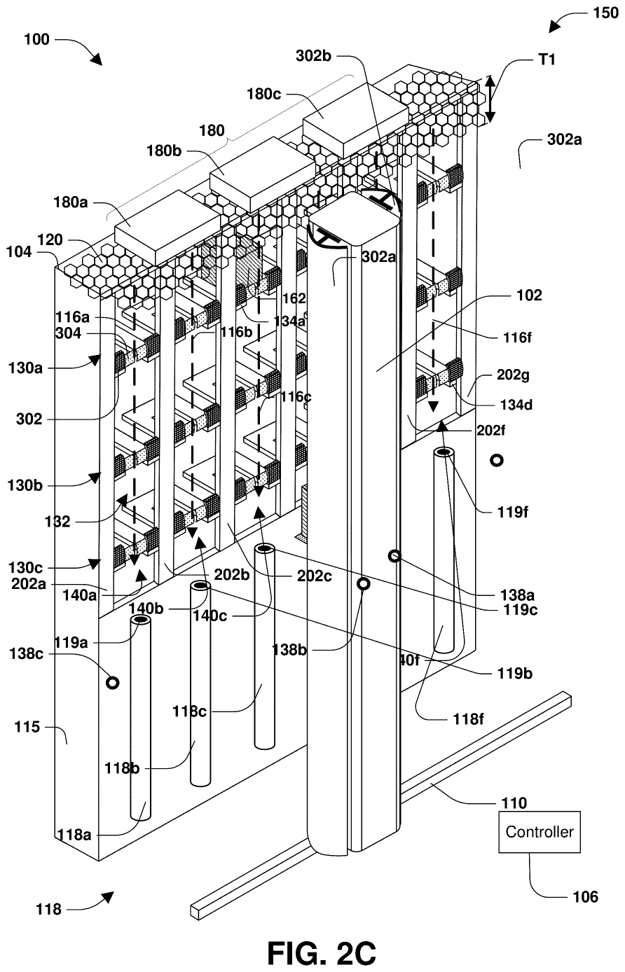

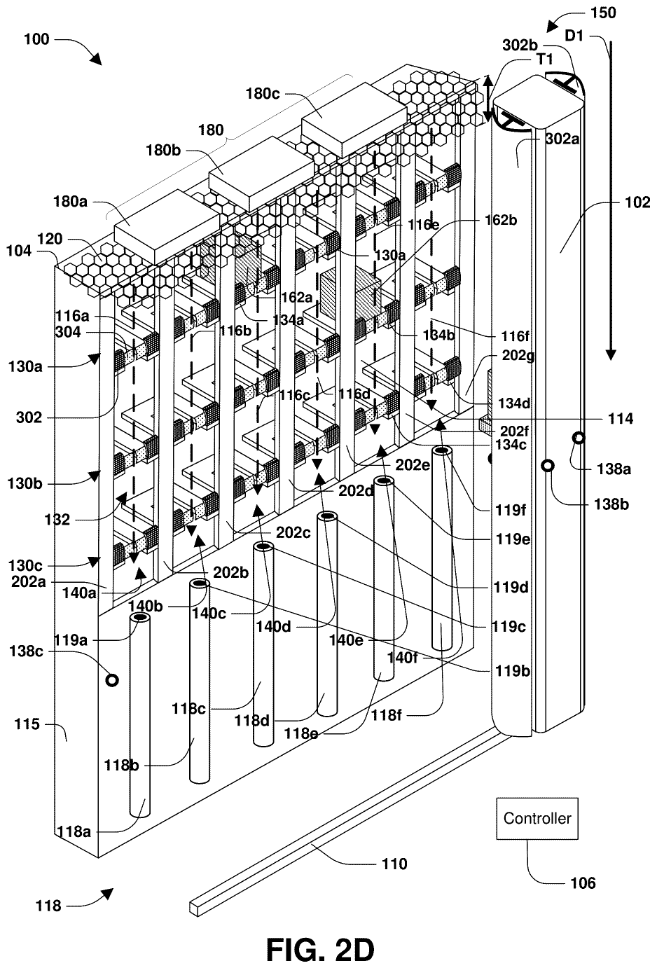

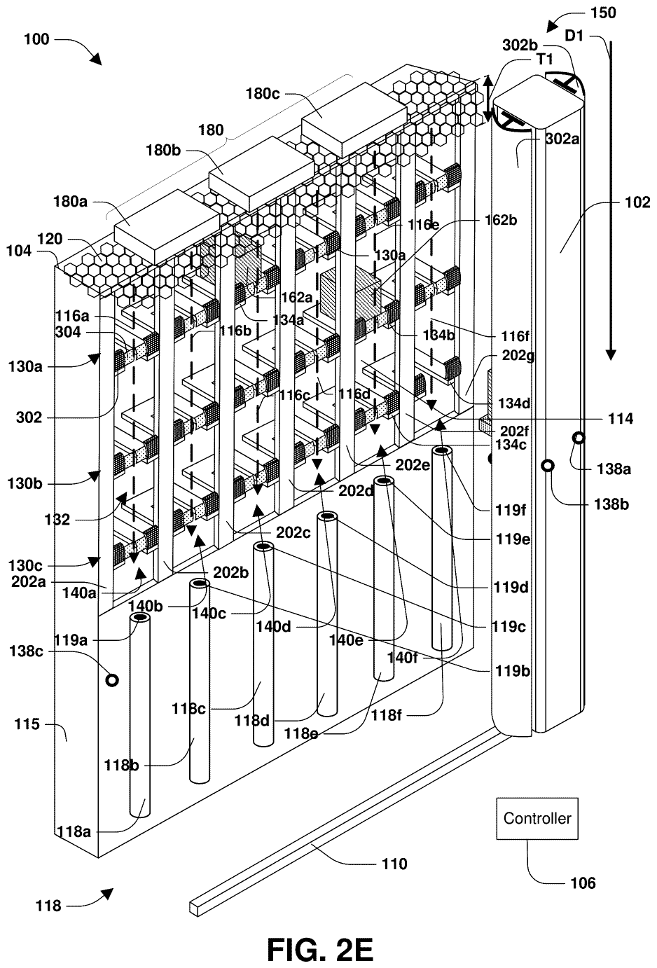

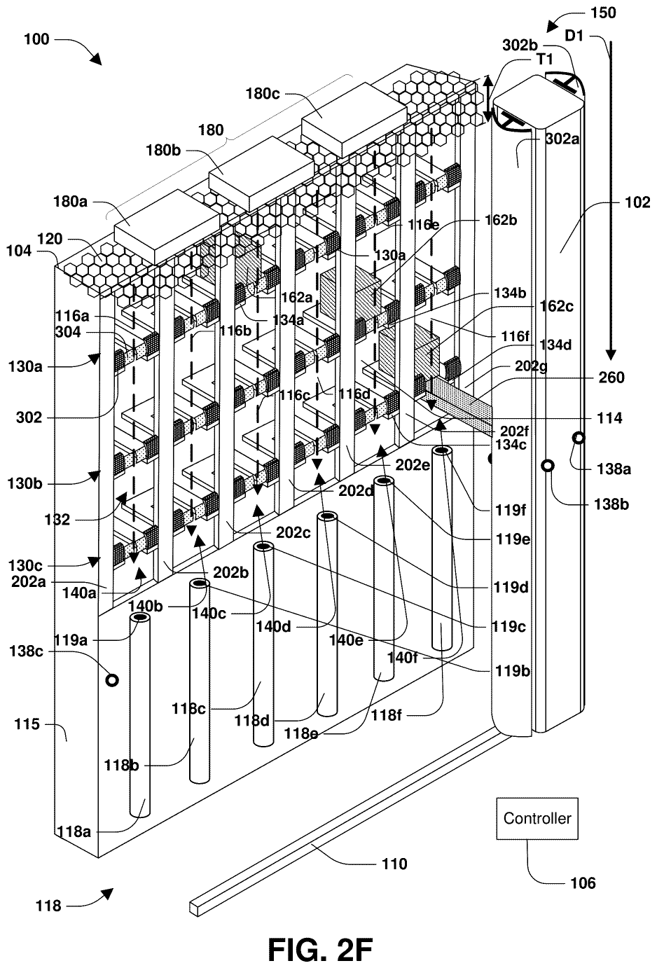

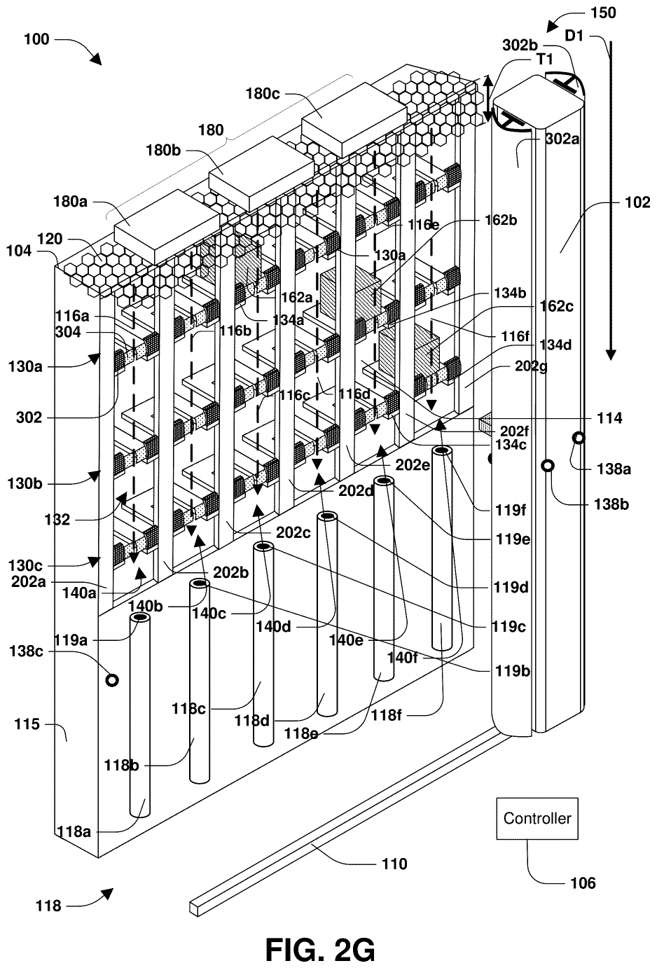

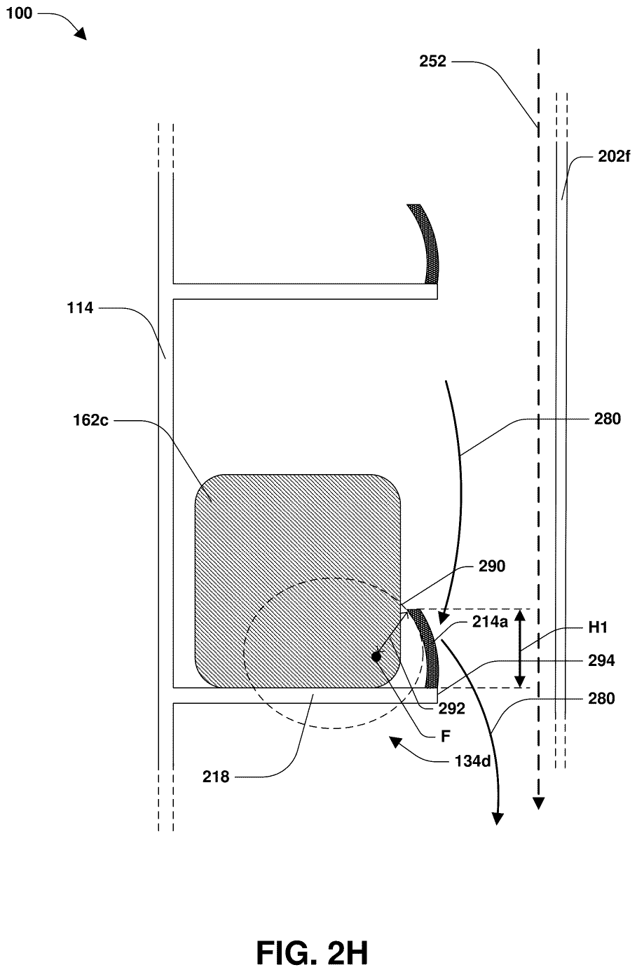

In some embodiments, the set of flow paths (through which air travels from the airflow rectification structure 120 to the set of vacuum units 118, for example) comprises one or more first flow paths associated with the set of air conduction panes. In some embodiments, the one or more first flow paths comprise at least one of (i) a flow path (not shown) through which air travels (in the first direction D1, for example) proximal the first air conduction pane 202a (e.g., the air is guided by the first air conduction pane 202a to flow in one or more directions, such as the first direction D1), (ii) a flow path (not shown) through which air travels (in the first direction D1, for example) proximal the second air conduction pane 202b (e.g., the air is guided by the second air conduction pane 202b to flow in one or more directions, such as the first direction D1), (iii) a flow path (not shown) through which air travels (in the first direction D1, for example) proximal the third air conduction pane 202c (e.g., the air is guided by the third air conduction pane 202c to flow in one or more directions, such as the first direction D1), (iv) a flow path (not shown) through which air travels (in the first direction D1, for example) proximal the fourth air conduction pane 202d (e.g., the air is guided by the fourth air conduction pane 202d to flow in one or more directions, such as the first direction D1), (v) a flow path (not shown) through which air travels (in the first direction D1, for example) proximal the fifth air conduction pane 202e (e.g., the air is guided by the fifth air conduction pane 202e to flow in one or more directions, such as the first direction D1), (vi) a flow path 252 (shown in FIG. 2H) through which air travels (in the first direction D1, for example) proximal the sixth air conduction pane 202f (e.g., the air is guided by the sixth air conduction pane 202f to flow in one or more directions, such as the first direction D1), (vii) a flow path (not shown) through which air travels (in the first direction D1, for example) proximal the seventh air conduction pane 202g (e.g., the air is guided by the seventh air conduction pane 202g to flow in one or more directions, such as the first direction D1), etc. In some embodiments, the set of air conduction panes conducts air (e.g., air from the airflow rectification structure 120) along the one or more first flow paths to at least one of (i) a space under one, some or all of the plurality of shelving units of the stocking apparatus 104, or (ii) the set of vacuum units 118.

FIG. 2A illustrates a front enlarged view of a portion of the stocking apparatus 104 with a pair of adjacent shelving units comprising a third shelving unit 134c and a fourth shelving unit 134d, in accordance with some embodiments. In some embodiments, the third shelving unit 134c comprises at least one of (i) one or more first stoppers, (ii) a first gate assembly, or (iii) a first shelf body 208. In some embodiments, the first shelf body 208 is configured to support a product unit (not shown) (e.g., the product unit is in contact with and/or rests upon the first shelf body 208 of the third shelving unit 134c). In some embodiments, the one or more first stoppers are configured to prevent the product unit from falling off the third shelving unit 134c. In some embodiments, a stopper of the one or more first stoppers protrudes upwards from the first shelf body 208 of the third shelving unit 134c, and thus the stopper provides resistance to the product unit escaping the third shelving unit 134c. In some embodiments, the one or more first stoppers comprise at least one of a stopper 204a, a stopper 204b, or one or more other stoppers. In some embodiments, the first gate assembly comprises at least one of a first gate 206a or a second gate 206b. In some embodiments, the first gate assembly is configured to control a state of a first stocking path between the stopper 204a and the stopper 204b. In some embodiments, each stopper of one, some or all of the one or more first stoppers comprises at least one of metal (e.g., steel) or other suitable material.

In some embodiments, the first gate assembly transitions between a gate closed state in which the first stocking path is closed and a gate open state in which the first stocking path is open. FIG. 2A depicts the first gate assembly in the gate closed state in which the first stocking path associated with the third shelving unit 134c is closed, in accordance with some embodiments. FIG. 2B depicts the first gate assembly in the gate open state in which the first stocking path associated with the third shelving unit 134c is open, in accordance with some embodiments. In some embodiments, the first gate assembly transitions from the gate open state to the gate closed state by at least one of (i) moving the first gate 206a in direction 222 (shown in FIG. 2A), or (ii) moving the second gate 206b in direction 224 (shown in FIG. 2A). In some embodiments, the first gate assembly transitions from the gate closed state to the gate open state by at least one of (i) moving the first gate 206a in direction 226 (shown in FIG. 2B) towards and/or into the stopper 204a, or (ii) moving the second gate 206b in direction 228 (shown in FIG. 2B) towards and/or into the stopper 204b. In some embodiments, at least one of the first gate 206a or the second gate 206b is moved to transition between the gate open state and the gate closed state using at least one of a motor, a gate driving mechanism, etc.

In some embodiments, the fourth shelving unit 134d comprises at least one of (i) one or more second stoppers, (ii) a second gate assembly, or (iii) a second shelf body 218. In some embodiments, a product unit 162c is stored in a storage location over the fourth shelving unit 134d. In some embodiments, the second shelf body 218 is configured to support the product unit 162c (e.g., the product unit 162c is in contact with and/or rests upon the second shelf body 218 of the fourth shelving unit 134d). In some embodiments, the one or more second stoppers are configured to prevent the product unit 162c from falling off the fourth shelving unit 134d. In some embodiments, a stopper of the one or more second stoppers protrudes upwards from the second shelf body 218 of the fourth shelving unit 134d, and thus the stopper provides resistance to the product unit 162c escaping the fourth shelving unit 134d. In some embodiments, the one or more second stoppers comprise at least one of a stopper 214a, a stopper 214b, or one or more other stoppers. In some embodiments, the second gate assembly comprises at least one of a third gate 216a or a fourth gate 216b. In some embodiments, the second gate assembly is configured to control a state of a second stocking path between the stopper 214a and the stopper 214b. In some embodiments, each stopper of one, some or all of the one or more second stoppers comprises at least one of metal (e.g., steel) or other suitable material.

In some embodiments, the second gate assembly transitions between a gate closed state in which the second stocking path is closed and a gate open state in which the second stocking path is open. FIG. 2A depicts the second gate assembly in the gate closed state in which the second stocking path associated with the fourth shelving unit 134d is closed, in accordance with some embodiments. FIG. 2B depicts the second gate assembly in the gate open state in which the second stocking path associated with the fourth shelving unit 134d is open, in accordance with some embodiments. In some embodiments, at least one of the third gate 216a or the fourth gate 216b is moved to transition between the gate open state and the gate closed state using at least one of a motor, a gate driving mechanism, etc.

In some embodiments, the second gate assembly is configured to open the second stocking path (by transitioning from the gate closed state to the gate open state) in response to receiving a stocking operation message indicative of a stocking operation. In some embodiments, the stocking operation message is transmitted to the second gate assembly by at least one of the controller 106 or the stocking vehicle 102. In some embodiments, the second gate assembly communicates with the stocking vehicle 102 over one or more communication protocols, such as E84 communication protocol or other suitable communication protocol. In some embodiments, the stocking operation comprises a put operation in which the product unit 162c is transferred, via the second stocking path, from a load support component of the stocking vehicle 102 to the storage location over the fourth shelving unit 134d. In some embodiments, the stocking operation comprises a get operation in which the product unit 162c is transferred, via the second stocking path, from the storage location over the fourth shelving unit 134d to the load support component of the stocking vehicle 102. In some embodiments, the second gate assembly is configured to close the second stocking path (by transitioning from the gate open state to the gate closed state) in response to completion of the stocking operation. In some embodiments, the second gate assembly closes the second stocking path in response to receiving a stocking operation completion message indicative of completion of the stocking operation.

In some embodiments, the product unit 162c comprises a wafer storage device. In some embodiments, the wafer storage device comprises at least one of a front opening unified pod (FOUP), a cassette pod, a reticle pod, or other type of wafer storage device. In some embodiments, the wafer storage device is used to store one or more wafers. In some embodiments, the one or more wafers comprise a batch of wafers. In some embodiments, the one or more wafers comprise at least one of one or more semiconductor wafers, one or more photomasks, one or more semiconductor devices, one or more dies, etc. In some embodiments, the one or more wafers are stacked vertically in the wafer storage device. In some embodiments, the one or more wafers are supported by a support frame, of the wafer storage device, having at least one of wafer shelves or wafer slots. In some embodiments, a wafer stored in the wafer storage device comprises one or more layers, such as at least one of a semiconductor layer, a conductor layer, or an insulator layer.

FIGS. 2C-2G illustrates operation of the automated material handling system 100 in association with a first stocking operation associated with the fourth shelving unit 134d, in accordance with some embodiments. In some embodiments, the first stocking operation comprises a put operation in which the product unit 162c is transferred to the storage location over the fourth shelving unit 134d. In some embodiments, the controller 106 initiates the first stocking operation in response to completion of a first process, such as a semiconductor fabrication process, on one or more wafers stored in the product unit 162c. In some embodiments, the first process is performed by a first process machine (not shown).

In some embodiments, the first process machine comprises at least one of (i) physical vapor deposition (PVD) equipment, (ii) chemical vapor deposition (CVD) equipment, (iii) plating equipment, (iv) etching equipment, such as at least one of plasma etching equipment, wet etching equipment, dry etching equipment, reactive-ion etching (RIE) equipment, atomic layer etching (ALE) equipment, buffered oxide etching equipment, or ion beam milling equipment, (v) lithography equipment, (vi) chemical mechanical planarization (CMP) equipment, or (vii) other equipment. In some embodiments, the first process comprises at least one of (i) a PVD process, (ii) a CVD process, (iii) a plating process, (iv) an etching process, such as at least one of a plasma etching process, a wet etching process or a dry etching process, (v) a lithographic equipment, (vi) a CMP process, or (vii) one or more other suitable processes.

In some embodiments, in response to completing the first process on a wafer, the wafer is removed from the first process machine and loaded into the product unit 162c. In some embodiments, multiple wafers are processed using the process machine at a time. In some embodiments, a single wafer is processed using the process machine at a time. In some embodiments, the process machine is used to perform the first process on each wafer of one, some or all wafers stored in the product unit 162c to produce a set of one or more processed wafers, and the set of one or more processed wafers are loaded into the product unit 162c. In some embodiments, the controller 106 initiates the first stocking operation in response to completion of the first process (e.g., in response to the set of one or more processed wafers being loaded into the product unit 162c) to store the set of one or more processed wafers for a period of time in the storage location over the fourth shelving unit 134d.

In some embodiments, the stocking vehicle 102 comprises a load support component 260 (shown in FIG. 2F) configured to carry the product unit 162c. FIG. 2C illustrates the stocking vehicle 102 at a first position relative to the track 110, in accordance with some embodiments. In some embodiments, the stocking vehicle 102 moves along the track 110 to a second position closer to the fourth shelving unit 134d. FIG. 2D illustrates the stocking vehicle 102 at the second position relative to the track 110, in accordance with some embodiments. In some embodiments, the stocking vehicle 102 moves to the second position based upon a vehicle control signal transmitted by the controller 106. In some embodiments, the vehicle control signal is indicative of a target storage location for the product unit 162c (e.g., the storage location over the fourth shelving unit 134d). In some embodiments, the controller 106 transmits the vehicle control signal indicative of the target storage location to the stocking vehicle 102 in response to initiating the first stocking operation.

In some embodiments, the second gate assembly is configured to open the second stocking path (by transitioning from the gate closed state to the gate open state) to allow the product unit 162c to be transferred from the load support component 260 to the storage location over the fourth shelving unit 134d. FIG. 2E illustrates the second gate assembly in the gate open state after transitioning from the gate closed state, in accordance with some embodiments. In some embodiments, the second gate assembly transitions from the gate closed state (shown in FIG. 2D) to the gate open state (shown in FIG. 2E) in response to reception (e.g., over E84 communication protocol or other suitable communication protocol) of a first stocking operation message from at least one of the stocking vehicle 102 or the controller 106. In some embodiments, the first stocking operation message is transmitted (by at least one of the stocking vehicle 102 or the controller 106) to trigger the second gate assembly in response to at least one of (i) initiation of the first stocking operation, (ii) a determination that the stocking vehicle 102 is within a threshold distance of the fourth shelving unit 134d, or (iii) a determination that the load support component 260 is within a threshold distance of the fourth shelving unit 134d.

In some embodiments, the stocking vehicle 102 is configured to transfer the product unit 162c to the storage location over the fourth shelving unit 134d while the second gate assembly is in the gate open state. FIG. 2F illustrates the stocking vehicle 102 moving at least one of the load support component 260 or the product unit 162c supported by the load support component 260 through the (opened) second stocking path to the storage location over the fourth shelving unit 134d, in accordance with some embodiments. In some embodiments, the product unit 162c is transferred from the load support component 260 to the storage location over the fourth shelving unit 134d using a mechanical device (not shown). In some embodiments, the stocking vehicle 102 comprises the mechanical device. In some embodiments, the stocking vehicle 102 does not comprise the mechanical device. In some embodiments, the stocking apparatus 104 comprises the mechanical device. In some embodiments, the stocking vehicle 102 is configured to retract the load support component 260 in response to the product unit 162c being stored in the storage location over the fourth shelving unit 134d.

In some embodiments, the second gate assembly is configured to close the second stocking path (by transitioning from the gate open state to the gate closed state) in response to completion of the first stocking operation. In some embodiments, the first stocking operation is considered completed when at least one of (i) the product unit 162c is (successfully) stored in the fourth shelving unit 134d, (ii) the load support component 260 is retracted, or (iii) the stocking vehicle 102 moves away from the fourth shelving unit 134d. In some embodiments, the second gate assembly closes the second stocking path in response to receiving a first stocking operation completion message indicative of completion of the first stocking operation. In some embodiments, the first stocking operation completion message is transmitted (by at least one of the stocking vehicle 102 or the controller 106) to trigger the second gate assembly in response to at least one of (i) a determination that the first stocking operation is completed, or (ii) a determination that the load support component 260 is outside the threshold distance of the fourth shelving unit 134d. FIG. 2G illustrates the automated material handling system 100 after the second gate assembly transitions from the gate open state to the gate closed state and the load support component 260 is retracted, in accordance with some embodiments.

In some embodiments, the product unit 162c is stored in the storage location over the fourth shelving unit 134d for a period of time until the product unit 162c is scheduled to be transferred to a different location, such as a second process machine (not shown) configured to perform a second process on one or more wafers stored in the product unit 162c. In some embodiments, a second stocking operation is performed to at least one of (i) retrieve the product unit 162c from the storage location over the fourth shelving unit 134d using a stocking vehicle (e.g., the stocking vehicle 102 or other stocking vehicle), or (ii) transfer the product unit 162c to the second process machine. In some embodiments, the second stocking operation comprises a get operation in which the product unit 162c is transferred from the storage location over the fourth shelving unit 134d to a load support component (e.g., the load support component 260) of the stocking vehicle.

In some embodiments, the second gate assembly is configured to open the second stocking path (by transitioning from the gate closed state to the gate open state) to allow the product unit 162c to be transferred from the storage location over the fourth shelving unit 134d to the load support component via the get operation. In some embodiments, the second gate assembly transitions from the gate closed state to the gate open state in response to reception (e.g., over E84 communication protocol or other suitable communication protocol) of a second stocking operation message from at least one of the stocking vehicle or the controller 106. In some embodiments, the second stocking operation message is transmitted (by at least one of the stocking vehicle or the controller 106) to trigger the second gate assembly in response to at least one of (i) initiation of the second stocking operation, (ii) a determination that the stocking vehicle is within a threshold distance of the fourth shelving unit 134d, or (iii) a determination that the load support component is within a threshold distance of the fourth shelving unit 134d.

In some embodiments, the stocking vehicle is configured to transfer the product unit 162c from the storage location over the fourth shelving unit 134d to the load support component while the second gate assembly is in the gate open state. In some embodiments, the product unit 162c is transferred from the storage location over the fourth shelving unit 134d to the load support component using a mechanical device (not shown). In some embodiments, the stocking vehicle is configured to retract the load support component 260 in response to the product unit 162c being loaded onto the load support component.

In some embodiments, the second gate assembly is configured to close the second stocking path (by transitioning from the gate open state to the gate closed state) in response to completion of the second stocking operation (e.g., completion of the get operation). In some embodiments, the second stocking operation is considered completed when at least one of (i) the product unit 162c is not in the fourth shelving unit 134d, (ii) the load support component is retracted, or (iii) the stocking vehicle moves away from the fourth shelving unit 134d. In some embodiments, the second gate assembly closes the second stocking path in response to receiving a second stocking operation completion message indicative of completion of the second stocking operation. In some embodiments, the second stocking operation completion message is transmitted (by at least one of the stocking vehicle or the controller 106) to trigger the second gate assembly in response to at least one of (i) a determination that the second stocking operation is completed, or (ii) a determination that the load support component is outside the threshold distance of the fourth shelving unit 134d.

In some embodiments, the second process machine comprises at least one of (i) PVD equipment, (ii) CVD equipment, (iii) plating equipment, (iv) etching equipment, such as at least one of plasma etching equipment, wet etching equipment, dry etching equipment, RIE equipment, ALE equipment, buffered oxide etching equipment, or ion beam milling equipment, (v) lithography equipment, (vi) CMP equipment, or (vii) other equipment. In some embodiments, the second process comprises at least one of (i) a PVD process, (ii) a CVD process, (iii) a plating process, (iv) an etching process, such as at least one of a plasma etching process, a wet etching process or a dry etching process, (v) a lithographic equipment, (vi) a CMP process, or (vii) one or more other suitable processes.

FIG. 2H illustrates a side view of the fourth shelving unit 134d relative to the sixth air conduction pane 202f, in accordance with some embodiments. In some embodiments, the stopper 214a is curved. FIG. 2H depicts a dashed-line representation of a virtual extended surface 290 of the stopper 214a, in accordance with some embodiments. In some embodiments, an eccentricity associated with at least one of a curvature (e.g., arc) of the stopper 214a or the virtual extended surface 290 is at least about 0.5. In some embodiments, a distance 292 between a focus F associated with the virtual extended surface 290 and an end of the stopper 214a is between about five centimeters to about 15 centimeters. In some embodiments, an end 294 of the second shelf body 218 is aligned with the stopper 214a. In some embodiments, the second shelf body 218 and the stopper 214a are formed from a metal sheet. In some embodiments, a portion of the metal sheet is deformed (e.g., folded) to produce the stopper 214a. In some embodiments, the stopper 214a being curved at least one of (i) promotes (e.g., increases) laminar airflow, (ii) mitigates (e.g., reduces, inhibits and/or blocks) flow of air (e.g., particle-laden air) and/or particles into the fourth shelving unit 134d (e.g., particles that could potentially contaminate the product unit 162c and/or wafers stored in the product unit 162c if the particles were to freely enter the fourth shelving unit 134d), or (iii) mitigates (e.g., reduces, inhibits and/or blocks) airflow (e.g., longitudinal and/or lateral turbulence) in one or more directions away from the first direction D1. In some embodiments, the curvature of the stopper 214a reflects and/or redirects air 280 (e.g., particle-laden air) away from the fourth shelving unit 134d. A height H1 of the stopper 214a is at least one of (i) at least about 1 centimeter, or (ii) between about 1 centimeter to about 5 centimeters. Other values of the height H1 are within the scope of the present disclosure.

In some embodiments, the stopper 214b (not shown in FIG. 2H) is curved. In some embodiments, an eccentricity associated with a curvature (e.g., arc) of the stopper 214b is at least about 0.5. In some embodiments, the stopper 214b being curved at least one of (i) promotes laminar airflow, (ii) mitigates flow of air and/or particles into the fourth shelving unit 134d, or (iii) mitigates airflow (e.g., longitudinal and/or lateral turbulence) in one or more directions away from the first direction D1. A height (not shown) of the stopper 214b is at least one of (i) at least about 1 centimeter, or (ii) between about 1 centimeter to about 5 centimeters. Other values of the height of the stopper 214b are within the scope of the present disclosure. In some embodiments, a side profile of the stopper 214b is the same as or similar to a side profile of the stopper 214a. In some embodiments, the height of the stopper 214b is the same as or similar to the height of the stopper 214a.

In some embodiments, the third gate 216a (not shown in FIG. 2H) is curved. In some embodiments, an eccentricity associated with a curvature (e.g., arc) of the third gate 216a is at least about 0.5. In some embodiments, the third gate 216a being curved at least one of (i) promotes laminar airflow, (ii) mitigates flow of air and/or particles into the fourth shelving unit 134d, or (iii) mitigates airflow (e.g., longitudinal and/or lateral turbulence) in one or more directions away from the first direction D1. A height (not shown) of the third gate 216a is at least one of (i) at least about 1 centimeter, or (ii) between about 1 centimeter to about 5 centimeters. Other values of the height of the third gate 216a are within the scope of the present disclosure. In some embodiments, a side profile of the third gate 216a is the same as or similar to a side profile of the stopper 214a. In some embodiments, the height of the third gate 216a is the same as or similar to the height of the stopper 214a.

In some embodiments, the fourth gate 216b (not shown in FIG. 2H) is curved. In some embodiments, an eccentricity associated with a curvature (e.g., arc) of the fourth gate 216b is at least about 0.5. In some embodiments, the fourth gate 216b being curved at least one of (i) promotes laminar airflow, (ii) mitigates flow of air and/or particles into the fourth shelving unit 134d, or (iii) mitigates airflow (e.g., longitudinal and/or lateral turbulence) in one or more directions away from the first direction D1. A height (not shown) of the fourth gate 216b is at least one of (i) at least about 1 centimeter, or (ii) between about 1 centimeter to about 5 centimeters. Other values of the height of the fourth gate 216b are within the scope of the present disclosure. In some embodiments, a side profile of the fourth gate 216b is the same as or similar to a side profile of the stopper 214a. In some embodiments, the height of the fourth gate 216b is the same as or similar to the height of the stopper 214a.

In some embodiments, the automated material handling system 100 comprises one or more windshields coupled to the stocking vehicle 102. FIG. 3 illustrates a top view of the stocking vehicle 102 with the one or more windshields while the stocking vehicle 102 travels in a second direction D2, in accordance with some embodiments. In some embodiments, the one or more windshields comprise at least one of a first windshield 302a or a second windshield 302b. In some embodiments, each windshield of one, some, or all of the one or more windshields has a height that is about equal to or greater than a height of the stocking vehicle 102. In some embodiments, a first corner 304a of the stocking vehicle 102 is rounded. In some embodiments, at least one of (i) an eccentricity associated with a curvature of the first corner 304a is at least about 0.1 or (ii) a radius associated with the first corner 304a is at least about 1 centimeter. In some embodiments, a second corner 304b of the stocking vehicle 102 is rounded. In some embodiments, at least one of (i) an eccentricity associated with a curvature of the second corner 304b is at least about 0.1 or (ii) a radius associated with the second corner 304b is at least about 1 centimeter. In some embodiments, a third corner 304c of the stocking vehicle 102 is rounded. In some embodiments, at least one of (i) an eccentricity associated with a curvature of the third corner 304c is at least about 0.1 or (ii) a radius associated with the third corner 304c is at least about 1 centimeter. In some embodiments, a fourth corner 304d of the stocking vehicle 102 is rounded. In some embodiments, at least one of (i) an eccentricity associated with a curvature of the fourth corner 304d is at least about 0.1 or (ii) a radius associated with the fourth corner 304d is at least about 1 centimeter.

In some embodiments, the one or more windshields and/or one or more corners of the stocking vehicle 102 being rounded at least one of (i) promote (e.g., increase) laminar airflow relative to the stocking vehicle 102 during movement of the stocking vehicle 102, (ii) mitigate (e.g., reduce, inhibit and/or block) turbulence, (iii) improve aerodynamics of the stocking vehicle 102, or (iv) reduce drag of the stocking vehicle 102 during movement of the stocking vehicle 102. A laminar flow profile associated with a laminar airflow produced by movement of the stocking vehicle 102 is shown with lines L1 and L2 in FIG. 3, in accordance with some embodiments.

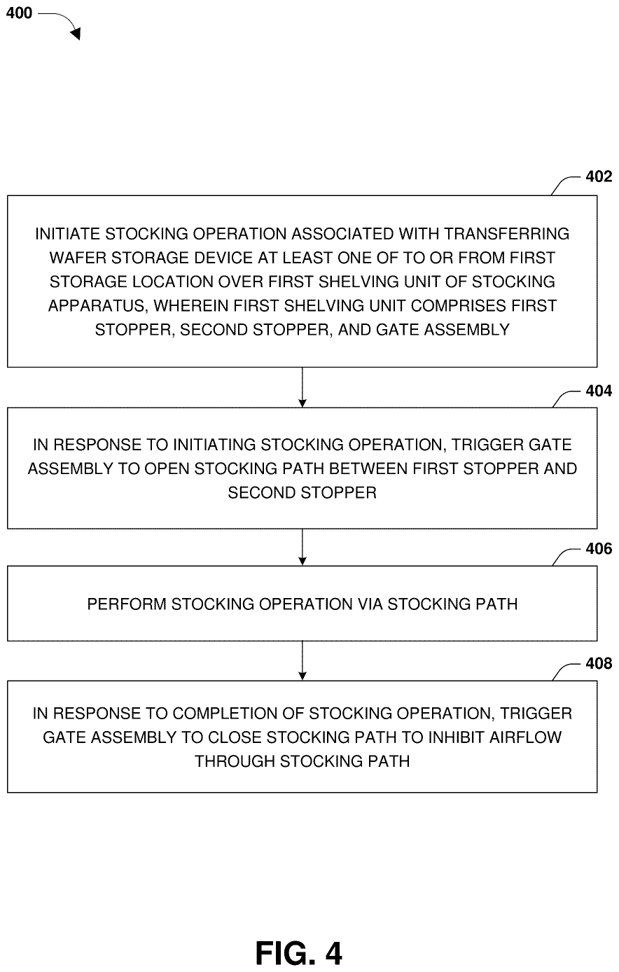

A method 400 is illustrated in FIG. 4 in accordance with some embodiments. At 402, a stocking operation (e.g., at least one of the first stocking operation, the second stocking operation, etc.) associated with transferring a wafer storage device (e.g., the product unit 162c) at least one of to or from a first storage location over a first shelving unit (e.g., the fourth shelving unit 134d) of a stocking apparatus (e.g., the stocking apparatus 104), wherein the first shelving unit comprises a first stopper (e.g., the stopper 214a), a second stopper (e.g., the stopper 214b), and a gate assembly (e.g., at least one of the third gate 216a or the fourth gate 216b). At 404, in response to initiating the stocking operation, the gate assembly is triggered to open a stocking path between the first stopper and the second stopper. At 406, the stocking operation is performed via the stocking path. At 408, in response to completion of the stocking operation, the gate assembly is triggered to close the stocking path to inhibit airflow through the stocking path.

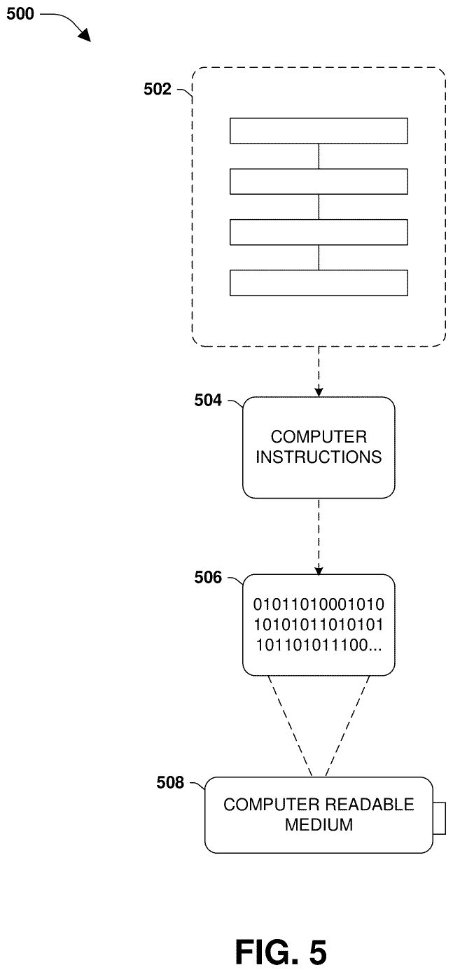

One or more embodiments involve a computer-readable medium comprising processor-executable instructions configured to implement one or more of the techniques presented herein. An exemplary computer-readable medium is illustrated in FIG. 5, wherein the embodiment 500 comprises a computer-readable medium 508 (e.g., a CD-R, DVD-R, flash drive, a platter of a hard disk drive, etc.), on which is encoded computer-readable data 506. This computer-readable data 506 in turn comprises a set of processor-executable computer instructions 504 configured to implement one or more of the principles set forth herein when executed by a processor. In some embodiments 500, the processor-executable computer instructions 504 are configured to implement a method 502, such as at least some of the aforementioned method(s) when executed by a processor. In some embodiments, the processor-executable computer instructions 504 are configured to implement a system, such as at least some of the one or more aforementioned systems when executed by a processor. In some embodiments, the processor-executable computer instructions 504 are configured to implement an apparatus, such as at least some of the one or more aforementioned apparatuses when executed by a processor. Many such computer-readable media may be devised by those of ordinary skill in the art that are configured to operate in accordance with the techniques presented herein.

In some embodiments, an automated material handling system is provided. The automated material handling system includes a stocking apparatus including a plurality of shelving units. The automated material handling system includes an airflow rectification structure overlying one or more of the plurality of shelving units. The automated material handling system includes a vacuum unit under one or more of the plurality of shelving units, wherein the airflow rectification structure is configured to conduct air along one or more flow paths to the vacuum unit.

In some embodiments, an automated material handling system is provided. The automated material handling system includes a stocking apparatus including a first shelving unit including a first stopper, a second stopper, and a gate assembly configured to control a state of a stocking path between the first stopper and the second stopper. The automated material handling system includes a stocking vehicle configured to perform a stocking operation associated with transferring a wafer storage device at least one of to or from a first storage location over the first shelving unit. The gate assembly is configured to open the stocking path in response to receiving a stocking operation message indicative of the stocking operation. The gate assembly is configured to close the stocking path to inhibit airflow through the stocking path in response to completion of the stocking operation.

In some embodiments, a method is provided. The method includes initiating a stocking operation associated with transferring a wafer storage device at least one of to or from a first storage location over a first shelving unit of a stocking apparatus, wherein the first shelving unit includes a first stopper, a second stopper, and a gate assembly. The method includes triggering, in response to initiating the stocking operation, the gate assembly to open a stocking path between the first stopper and the second stopper. The method includes performing the stocking operation via the stocking path. The method includes triggering, in response to completion of the stocking operation, the gate assembly to close the stocking path to inhibit airflow through the stocking path.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

Although the subject matter has been described in language specific to structural features or methodological acts, it is to be understood that the subject matter of the appended claims is not necessarily limited to the specific features or acts described above. Rather, the specific features and acts described above are disclosed as example forms of implementing at least some of the claims.

Various operations of embodiments are provided herein. The order in which some or all of the operations are described should not be construed to imply that these operations are necessarily order dependent. Alternative ordering will be appreciated having the benefit of this description. Further, it will be understood that not all operations are necessarily present in each embodiment provided herein. Also, it will be understood that not all operations are necessary in some embodiments.

It will be appreciated that layers, features, elements, etc. depicted herein are illustrated with particular dimensions relative to one another, such as structural dimensions or orientations, for example, for purposes of simplicity and ease of understanding and that actual dimensions of the same differ substantially from that Yeah illustrated herein, in some embodiments. Additionally, a variety of techniques exist for forming layers, regions, features, elements, etc. mentioned herein, such as at least one of etching techniques, planarization techniques, implanting techniques, doping techniques, spin-on techniques, sputtering techniques, growth techniques, or deposition techniques such as chemical vapor deposition (CVD), for example.

Moreover, “exemplary” and/or the like is used herein to mean serving as an example, instance, illustration, etc., and not necessarily as advantageous. As used in this application, “or” is intended to mean an inclusive “or” rather than an exclusive “or”. In addition, “a” and “an” as used in this application and the appended claims are generally to be construed to mean “one or more” unless specified otherwise or clear from context to be directed to a singular form. Also, at least one of A and B and/or the like generally means A or B or both A and B. Furthermore, to the extent that “includes”, “having”, “has”, “with”, or variants thereof are used, such terms are intended to be inclusive in a manner similar to the term “comprising”. Also, unless specified otherwise, “first,” “second,” or the like are not intended to imply a temporal aspect, a spatial aspect, an ordering, etc. Rather, such terms are merely used as identifiers, names, etc. for features, elements, items, etc. For example, a first element and a second element generally correspond to element A and element B or two different or two identical elements or the same element.

Also, although the disclosure has been shown and described with respect to one or more implementations, equivalent alterations and modifications will occur to others of ordinary skill in the art based upon a reading and understanding of this specification and the annexed drawings. The disclosure comprises all such modifications and alterations and is limited only by the scope of the following claims. In particular regard to the various functions performed by the above described components (e.g., elements, resources, etc.), the terms used to describe such components are intended to correspond, unless otherwise indicated, to any component which performs the specified function of the described component (e.g., that is functionally equivalent), even though not structurally equivalent to the disclosed structure. In addition, while a particular feature of the disclosure may have been disclosed with respect to only one of several implementations, such feature may be combined with one or more other features of the other implementations as may be desired and advantageous for any given or particular application.

What is claimed is:

1. An automated material handling system, comprising:
a stocking apparatus comprising a plurality of shelving units;
an airflow rectification structure overlying one or more of the plurality of shelving units; and
a vacuum unit under one or more of the plurality of shelving units, wherein the airflow rectification structure is configured to conduct air along one or more flow paths to the vacuum unit.

2. The automated material handling system of claim 1, comprising:
an air particulate sensor configured to measure an air particulate metric associated with a stocking environment of the automated material handling system, wherein operation of the vacuum unit is based upon the air particulate metric.

3. The automated material handling system of claim 2, wherein:
the vacuum unit is activated to intake air in response to the air particulate metric meeting a first air particulate threshold.

4. The automated material handling system of claim 3, wherein:
after the vacuum unit is activated, the vacuum unit is deactivated to cease intake of air in response to an updated value of the air particulate metric not meeting a second air particulate threshold.

5. The automated material handling system of claim 1, comprising:
a fan unit overlying the airflow rectification structure, wherein the fan unit is configured to emit an air stream to the airflow rectification structure.

6. The automated material handling system of claim 5, wherein:
the fan unit comprises a filter configured to filter air particles from air to produce filtered air, wherein the air stream comprises the filtered air.

7. The automated material handling system of claim 5, comprising:
an air particulate sensor configured to measure an air particulate metric associated with a stocking environment of the automated material handling system, wherein a flow rate of the air stream is controlled based upon the air particulate metric.

8. The automated material handling system of claim 1, wherein:
the airflow rectification structure comprises a honeycomb arrangement.

9. The automated material handling system of claim 1, wherein:
a first shelving unit of the plurality of shelving units comprises a first stopper; and
the first stopper is curved.

10. The automated material handling system of claim 9, wherein:
the first shelving unit comprises:
a second stopper; and
a gate assembly configured to control a state of a stocking path between the first stopper and the second stopper.

11. The automated material handling system of claim 10, wherein:
the gate assembly is configured to open the stocking path in response to receiving a stocking operation message indicative of a stocking operation.

12. The automated material handling system of claim 11, wherein:
the gate assembly is configured to close the stocking path in response to completion of the stocking operation.

13. The automated material handling system of claim 11, comprising:
a stocking vehicle configured to perform the stocking operation.

14. The automated material handling system of claim 13, wherein the stocking operation comprises:
a put operation comprising transferring, via the stocking path, a wafer storage device from a load support component of the stocking vehicle to a first storage location over the first shelving unit.

15. The automated material handling system of claim 13, wherein the stocking operation comprises:
a get operation comprising transferring, via the stocking path, a wafer storage device from a first storage location over the first shelving unit to a load support component of the stocking vehicle.

16. The automated material handling system of claim 13, comprising:
a windshield coupled to the stocking vehicle.

17. An automated material handling system, comprising:
a stocking apparatus comprising a first shelving unit comprising a first stopper, a second stopper, and a gate assembly configured to control a state of a stocking path between the first stopper and the second stopper; and
a stocking vehicle configured to perform a stocking operation associated with transferring a wafer storage device at least one of to or from a first storage location over the first shelving unit, wherein:
the gate assembly is configured to open the stocking path in response to receiving a stocking operation message indicative of the stocking operation; and
the gate assembly is configured to close the stocking path to inhibit airflow through the stocking path in response to completion of the stocking operation.

18. The automated material handling system of claim 17, wherein at least one of:
the first stopper is curved; or
the second stopper is curved.

19. A method, comprising:
initiating a stocking operation associated with transferring a wafer storage device at least one of to or from a first storage location over a first shelving unit of a stocking apparatus, wherein the first shelving unit comprises a first stopper, a second stopper, and a gate assembly;
in response to initiating the stocking operation, triggering the gate assembly to open a stocking path between the first stopper and the second stopper;
performing the stocking operation via the stocking path; and
in response to completion of the stocking operation, triggering the gate assembly to close the stocking path to inhibit airflow through the stocking path.

20. The method of claim 19, wherein performing the stocking operation comprises at least one of:
performing, using a stocking vehicle, a put operation comprising transferring, via the stocking path, the wafer storage device from a load support component of the stocking vehicle to the first storage location over the first shelving unit; or
performing, using the stocking vehicle, a get operation comprising transferring, via the stocking path, the wafer storage device from the first storage location over the first shelving unit to the load support component of the stocking vehicle.
